(19) United States
(12) Patent Application Publication
(10) Pub. No.: US 2007/0157947 A1
(43) Pub. Date: Jul. 12, 2007

(54) Substrate drying apparatus and method of substrate drying using the same

(76) Inventors: Deok Ho Kim, Yongin-si (KR); Sung Ho Hong, Yongin-si (KR); Suk Hee Lee, Yongin-si (KR); Jong Pal Ahn, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/648,553

(22) Filed: Jan. 3, 2007

(30) Foreign Application Priority Data
Jan. 12, 2006 (KR) 10-2006-0003412

(51) Int. Cl. B05D 3/02; C23G 1/00; B08B 3/00; H01L 21/306

(52) U.S. Cl. 134/2; 427/372.2; 134/95.2; 156/345.11

(57) ABSTRACT

A substrate drying apparatus, including a cleaning bath having a liquid supply unit, a drying tank having a gas supply unit and at least one nozzle in fluid communication with the gas supply unit, and a transfer unit for transferring a substrate from the cleaning bath to the drying tank. The apparatus of the present invention may be used in a substrate drying method, including supplying alternating dry gas mixture and inert gas to dry a substrate.

### BACKGROUND OF THE INVENTION

1. Field of the Invention

The present invention relates to equipment providing drying of a substrate. In particular, the present invention relates to a substrate drying apparatus and a method of substrate drying using the same having improved capabilities of removing liquid or moisture from a surface of the substrate.

2. Discussion of the Related Art

In general, semiconductor manufacturing processes, e.g., LCD or wafer manufacturing, may include wet cleaning of a substrate and subsequent drying thereof. The drying of the substrate may be performed, for example, by a spin dryer, an Iso-Propyl Alcohol (IPA) vapor dryer, a Marangoni dryer, and so forth.

The spin dryer may employ a centrifugal force, i.e., means of rotation, to dry the substrate, thereby failing to dry parts of the substrate that are located beyond the boundary created by the centrifugal force. Additionally, use of a spin dryer may increase the overall risk of damage to the substrate due to the centrifugal force.

The IPA vapor dryer may employ IPA at high temperatures, i.e., temperature of about 180° C. or more, to generate IPA vapor capable of absorbing liquid or moisture from a surface of a substrate and metathesizing it. However, the use of IPA vapors for drying a substrate may not be efficient for drying moisture from parts of a substrate that are located outside the vapor range. More importantly, use of IPA vapor may increase the risk of substrate flammability.

The Marangoni dryer may employ surface tension differential between pure liquid, e.g., water, and IPA in order to dry a substrate. In particular, the Marangoni dryer may include forming an IPA layer on a substrate surface containing moisture, e.g., water, in order to induce flow of the moisture from the substrate. However, drying by way of a Maragoni dryer may not be sufficient because even a small shift of the substrate may affect the surface tension of the liquid, and, thereby, modify the potential surface tension differential between the liquid and the IPA, and the subsequent moisture extraction.

Accordingly, there remains a need for an apparatus capable of providing efficient drying of a substrate while minimizing its potential damage.

### SUMMARY OF THE INVENTION

The present invention is therefore directed to equipment and method capable of drying a substrate, which substantially overcome one or more of the problems due to the limitations and disadvantages of the related art.

It is therefore a feature of an embodiment of the present invention to provide a substrate drying apparatus capable of removing liquid or moisture from a substrate.

It is another feature of the present invention to provide a method of drying a substrate using a substrate drying apparatus capable of providing efficient substrate drying while minimizing its potential damage.

At least one of the above and other features and advantages of the present invention may be realized by providing a substrate drying apparatus, including a cleaning bath having a liquid supply unit, a drying tank having a gas supply unit and at least one nozzle in fluid communication with the gas supply unit, and a transfer unit for transferring a substrate from the cleaning bath to the drying tank.

The drying tank may be formed above the cleaning bath. Additionally, the drying tank may be dome-shaped. The transfer unit may be a vertical transfer unit formed between the cleaning bath and the drying tank. The apparatus may further include a plurality of nozzles.

The gas supply unit may include a polarized organic solvent supply unit and an inert gas supply unit. The inert gas supply unit may include a heating unit and a flow rate adjusting unit.

The nozzle may be a coaxial tube having an inner tube and an outer tube. The inner tube and outer tube may include a plurality of inner and outer orifices, respectively. The plurality of inner and outer orifices may include at least 10 orifices each. Each inner and outer orifice may have an inside diameter of from about 0.3 mm to about 2.0 mm.

In another aspect of the present invention, there is provided a method of drying a substrate, including placing a substrate into a cleaning bath, supplying liquid to the cleaning bath to clean the substrate, transferring the clean substrate into a drying tank, supplying a dry gas mixture for a predetermined amount of time into the drying tank, supplying an inert gas for a predetermined amount of time into the drying tank, and repeating the supplying of the dry gas mixture and the supplying of the inert gas to dry the substrate.

Supplying the dry gas mixture may include supplying a mixture of an inert gas with any one of IPA, acetone, acetone nitrile, methanol, ethanol, and mixtures thereof.

Supplying the dry gas mixture for a predetermined amount of time and supplying the inert gas for a predetermined amount of time may include spraying the gas mixture and the inert gas into the drying tank for about 10 to about 120 seconds. Supplying the dry gas mixture and supplying the inert gas may also include spraying the gas mixture and the inert gas into the drying tank at a flow rate of from about 20 l/min to about 200 l/min at a temperature of from about 20° C. to about 250° C.

Repeating the supplying of the dry gas mixture and the supplying of the inert gas may be performed at least twice. Supplying liquid may include supplying water.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a schematic view of a configuration of a substrate drying apparatus according to a an embodiment of the present invention;

FIG. 2 illustrates a transmitted perspective view of a nozzle of the substrate drying apparatus in FIG. 1; and

FIGS. 3Aa to 3C illustrate schematic views of a method of drying a substrate using the substrate drying apparatus in FIG. 1.

### DETAILED DESCRIPTION OF THE INVENTION

Korean Patent Application No. 2006-0003412, filed on Jan. 12, 2006, in the Korean Intellectual Property Office, and entitled: “Substrate Drying Apparatus and Method of Drying Substrate Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers, elements, and regions may be exaggerated for clarity of illustration. It will also be understood that when a layer or element is referred to as being “on” another layer, element or substrate, it can be directly on the other layer, element or substrate, or intervening layers or elements may also be present. Further, it will be understood that when a layer or element is referred to as being “under” another layer or element, it can be directly under, or one or more intervening layers or elements may also be present. In addition, it will also be understood that when a layer or element is referred to as being “between” two layers or elements, it can be the only layer or element between the two layers or elements, or one or more intervening layers or elements may also be present. Like reference numerals refer to like elements throughout.

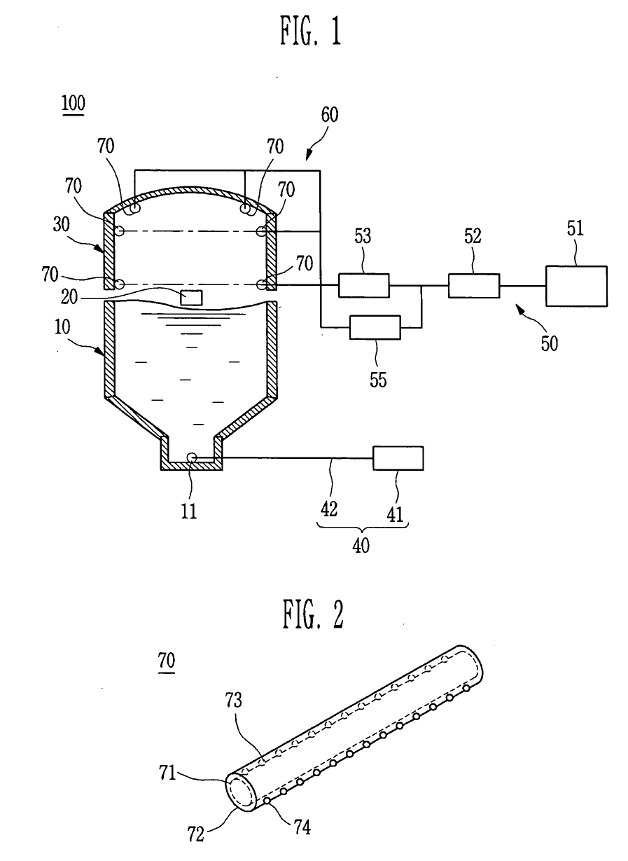

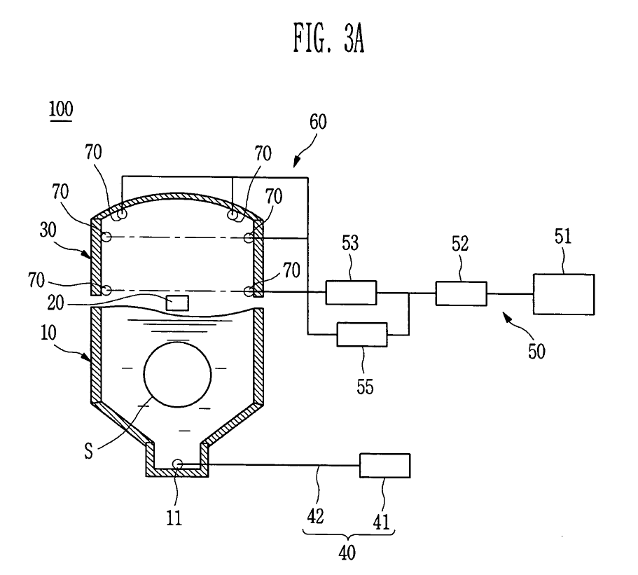

An exemplary embodiment of a substrate drying apparatus according to the present invention is more fully described below with reference to FIG. 1.

As illustrated in FIG. 1, a substrate drying apparatus 100 according to an embodiment of the present invention may include a cleaning bath 10, a drying tank 30 having at least one nozzle, and a transfer unit 20 for transferring a substrate from the cleaning bath 10 to the drying tank 30.

The cleaning bath 10 may be any suitable vessel for containing cleaning liquids, e.g., water, and providing a substrate cleaning therein. The cleaning bath 10 may include a liquid supply unit 40 for supplying a cleaning liquid into the cleaning bath 10 and a liquid supply hole 11 in connection with the liquid supply unit 40. Additionally, the cleaning bath 10 may include a heating unit (not shown) for heating the cleaning liquid. In this respect it should be noted that the preferred cleaning liquid may be water. However, outer suitable cleaning liquids are not excluded from the scope of this invention.

The liquid supply unit 40 may include a liquid supply source 41 and a liquid supply tube 42 positioned between the liquid supply source 41 and the cleaning bath 10 in order to supply cleaning liquid into the cleaning bath 10.

The liquid supply hole 11 of the cleaning bath 10 may be formed through any portion of the cleaning bath 10, and, preferably, it may be formed at the bottom of the cleaning bath 10, as illustrated in FIG. 1. The liquid supply hole 11 may be connected to the liquid supply tube 42, such that liquid supplied through the liquid supply tube 42 may flow into the cleaning bath 10 through the liquid supply hole 11. The liquid supply hole 11 may include a plurality of liquid supply orifices (not shown).

The drying tank 30 may be dome-shaped, i.e., have at least one radial edge, as illustrated in FIG. 1, to provide and maintain gas uniformity inside the drying tank 30. The drying tank 30 may be an air tight vessel, and it may be positioned above the cleaning bath 10, as illustrated in FIG. 1, such that the substrate drying apparatus 100 may form a vertically elongated structure. Accordingly, the transfer unit 20 may be positioned between the drying tank 30 and the cleaning bath 10. The transfer unit 20 may be any known transfer unit in the art that is employed for transferring substrates. Preferably, the transfer unit 20 may be a vertical transfer unit to provide convenient transfer medium between the cleaning bath 10 and the drying tank 30.

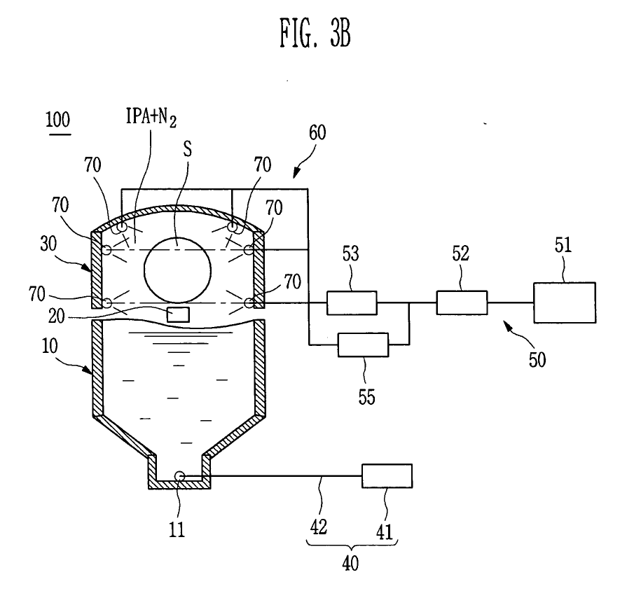

The drying tank 30 may include at least one nozzle. Preferably, the drying tank 30 may include a plurality of nozzles 70 to provide multiple inlets for gas into the drying tank 30. The number of nozzles formed in the drying tank 30 may be determined by a person skilled in the art according to the size of the drying tank 30 and the processing requirements. Each nozzle 70 may include a plurality of orifices to increase gas flow into the cleaning bath 10, as will be discussed in more detail with respect to FIG. 2.

As illustrated in FIG. 2, each nozzle 70 may have a coaxial double-tube shape including an inner tube 71 and an outer tube 72 and a plurality of orifices, preferably inner orifices 73 and outer orifices 74, formed on the inner tube 71 and outer tube 72, respectively The inner orifices 73 on the inner tube 71 and the outer orifices 74 on the outer tube 72 may be formed to face different directions or angles in order to improve gas flow.

The inner and outer tubes 71 and 72 of each nozzle 70 may be formed in any way known in the art, e.g., coaxially integrated within each other or as an attachable/detachable type. Preferably, the outer and outer tubes 71 and 72 may be integrated within each other to minimize gas leakage.

Without intending to be bound by theory, it is believed that employing a plurality of inner orifices 73 may provide a smooth and uniform flow of gas from the inner tube 71 into the outer tube 72. Further, it is believed that employing a plurality of outer orifices 74 may provide a uniform gas supply into the drying tank 30.

Preferably, the inner diameter of each of the inner and outer orifices 73 and 74 may be from about 0.3 mm to about 2.0 mm. An inner diameter below about 0.3 mm may cause gas spraying into the drying tank 30 at an excessive high pressure due to increase in pressure differential, thereby increasing a potential substrate damage. An inner diameter above about 2.0 mm may reduce the spraying effect and its uniformity upon delivery of the gas into the drying tank 30, thereby minimizing the efficiency of substrate drying.

Preferably, each of the plurality of inner and outer orifices 73 and 74 may include at least ten orifices. More preferably, each of the plurality of inner and outer orifices 73 and 74 may include more than ten orifices. A number of inner or outer orifices 73 and 74 below ten may cause an excessive high pressure and reduced spraying uniformity with respect to the size of a substrate to be dried in the drying tank 30.

Each nozzle 70 may be formed through a wall of the drying tank 30, and it may be in fluid communication with a gas supply source 50 by way of a gas supply tube 60. In particular, the gas supply tube 60 may be positioned between the drying tank 30 and the gas supply source 50 to supply gas, and preferably dry gas, into the drying tank 30 through the plurality of nozzles 70.

The gas supply source 50 may include an inert gas supply source 51 and a polarized organic solvent supply source 55. The inert gas supply source 51 may contain any inert gas capable of drying a substrate without chemically interacting therewith, such as nitrogen, argon, helium, neon, and mixtures thereof. Preferably, the inert gas supply source 51 may contain nitrogen. The inert gas supply source 51 may include a flow rate adjusting unit 52 to adjust the amount of inert gas supplied into the drying tank 30 and a heating unit 53 to enhance the dryness of the supplied gas.

The polarized organic solvent supply source 55 may contain any polarized organic gas capable of metathesizing liquid, such as iso-propyl alcohol (IPA), acetone, acetone nitrile, methanol, ethanol, and mixtures thereof. Preferably, the polarized organic solvent supply source 55 may contain IPA.

The polarized organic solvent supply source 55 and the inert gas supply source 51 may be connected therebetween and in fluid communication with gas supply tube 60, as can be seen in FIG. 1. Accordingly, the inert gas from the inert gas supply source 51 and organic solvent gas from the polarized organic solvent supply source 55 may be premixed and delivered simultaneously via the gas supply tube 60 and through the nozzle(s) 70 into the drying tank 30. In particular, a mixture of dry gas including an inert gas and a polarized organic solvent may be supplied into the inner tube 71 of the nozzle(s) 70, and, subsequently, the mixture of the dry gas may be transferred through the inner orifices 73 into the outer tube 72 of the nozzle(s) 70 in order to spray the dry gas mixture into the drying tank 30 through the outer orifices 74.

Alternatively, the inert gas supply source 51 and the polarized organic solvent supply source 55 may each be connected to a separate supply tube (not shown), such that each gas may be delivered separately into the nozzle(s) 70 of the drying tank 30, e.g., each separate supply tube may be connected to a separate nozzle 70. In particular, the inert gas may be supplied through the inner tube 71 of the nozzle(s) 70 and a polarized organic solvent may be supplied through the outer tube 72 of the nozzle(s) 70, or alternatively, a polarized organic solvent may be supplied through the inner tube 71 of the nozzle(s) 70, and an inert gas may be supplied through the outer tube 72 of the nozzle(s) 70. As such, the gas flowing through the inner tube 71 of the nozzle(s) 70 may be transferred into the outer tube 72 of the nozzle(s) 70 through the inner orifices 73 to mix with the gas flowing in the outer tube 72 of the nozzle(s) 70, and, subsequently, spray into the drying tank 30 through the outer orifices 74.

Additionally, the substrate drying apparatus according to an embodiment of the present invention may also include a flow rate adjusting valve (not shown). The flow rate adjusting valve may be formed between the gas supply tube 60 and nozzle(s) 70 in order to monitor the amount of dry gas supplied to each nozzle(s) 70.

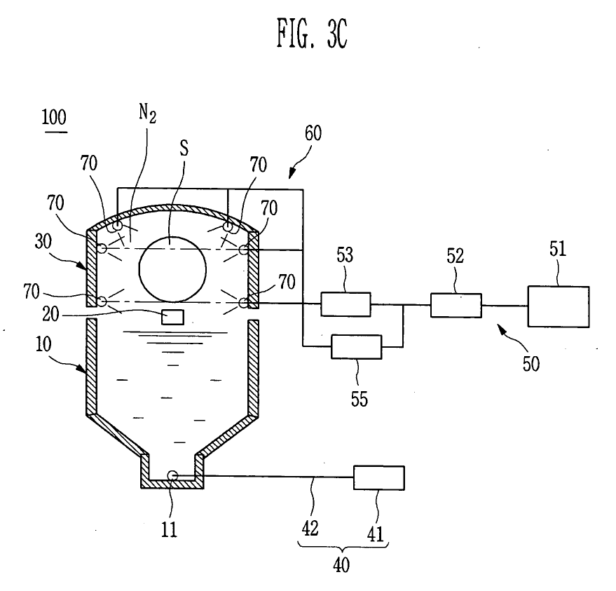

In accordance with another embodiment of the present invention, a method of drying a substrate using the substrate drying apparatus discussed previously with reference to FIGS. 1-2 will be discussed in detail below with respect to FIGS. 3A-3C., Accordingly, it should be noted that descriptions of the particular elements of the substrate drying apparatus 100 will not be repeated herein.

As illustrated in FIG. 3A, a substrate S may be placed into the cleaning bath 10, and liquid may be supplied through the liquid supply hole 11 into the cleaning bath 10 to facilitate cleaning of the substrate S. Preferably, the supplied liquid is water. More preferably, the supplied liquid is pure water, e.g., distilled water.

Next, the cleaned substrate S may be transferred into the drying tank 30 through the transfer unit 20 for the purpose of drying. Once the substrate S is place inside the drying tank 30, at least four drying steps may be employed.

The first drying step may include supplying a mixture of dry gas into the drying tank 30 through the nozzle(s) 70 for a predetermined amount of time, as illustrated in FIG. 3B. A “mixture of dry gas” may refer to a mixture including a polarized organic solvent and an inert gas.

After a predetermined amount of time, supplying of the mixture of dry gas into the drying tank 30 through the nozzle(s) 70 may be paused, and a second drying step may begin. In other words, supplying of only inert gas, e.g., nitrogen, may be provided into the drying tank 30 through the nozzle(s) 70 for a predetermined amount of time as illustrated in FIG. 3C. Subsequently, after the predetermined amount of time, supplying of the inert gas into the drying tank 30 through the nozzle(s) 70 may be paused, and the first and second drying steps may be repeated at least once as third and fourth drying steps. Preferably, the first and second drying steps may be repeated more than once to provide sufficient moisture removal from the substrate S.

Without intending to be bound by theory, it is believed that the multiple drying steps including alternating gas mixtures may be advantageous for improving the drying process of the substrate. In particular, it is believed that after a predetermined amount of time the mixture of dry gas and the moisture embedded in the substrate may reach specific concentrations inside the drying tank 30 to achieve an equilibrium state, thereby slowing down any further drying, i.e., moisture extraction from the substrate. Accordingly, alternating the drying gas in order to modify the concentrations of the gas species within the drying tank 30 may be beneficial in order to disturb the equilibrium state inside the drying tank 30, and, thereby, facilitate further drying process, i.e., extraction of moisture from the substrate.

As mentioned previously with respect to the embodiment described with reference to FIGS. 1-2, the polarized organic solvent supply gas may be any one of iso-propyl alcohol (IPA), acetone, acetone nitrile, methanol, ethanol, and mixtures thereof. Preferably, the polarized organic solvent supply gas may be IPA. The inert gas supply may be any one of nitrogen, argon, helium, neon, and mixtures thereof. Preferably, the inert gas supply may be nitrogen.

The predetermined amount of time employed to supply dry gas into the drying tank 30, i.e., either the mixture of dry gas or the inert gas alone, may be from about 10 seconds to about 120 seconds. The flow rate of each dry gas, i.e., either mixture of dry gas or the inert gas alone, into the drying tank 30 may be from about 20 L/min to about 200 L/min at a temperature of from about 2020 C. to about 250° C.

It should be noted that employing a predetermined amount of time below about 10 seconds may not be sufficient to provide drying due to short time intervals and frequent gas exchange. Employing a predetermined amount of time above about 120 seconds may minimize throughput due to lengthy drying cycles.

It should also be noted that a flow rate below about 20 l/min may minimize drying due to low flow rate, and, thereby, increase the overall drying cycle. Employing a flow rate above about 200 l/min may cause excessive flow of dry air, which may cause non-uniform drying.

It should further be noted that employing gas flow rates at temperatures below about 20° C. may cause substrate staining, while employing gas flow rates at temperatures above about 250° C. may increase substrate flammability due to use of organic solvents.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A substrate drying apparatus, comprising:
a cleaning bath having a liquid supply unit;
a drying tank having a gas supply unit and at least one nozzle in fluid communication with the gas supply unit; and
a transfer unit for transferring a substrate from the cleaning bath to the drying tank.

2. The apparatus as claimed in claim 1, wherein the drying tank is formed above the cleaning bath.

3. The apparatus as claimed in claim 1, wherein the gas supply unit comprises a polarized organic solvent supply unit and an inert gas supply unit.

4. The apparatus as claimed in claim 3, wherein the inert gas supply unit comprises a heating unit and a flow rate adjusting unit.

5. The apparatus as claimed in claim 1, further comprising a plurality of nozzles.

6. The apparatus as claimed in claim 1, wherein the nozzle is a coaxial tube having an inner tube and an outer tube.

7. The apparatus as claimed in claim 6, wherein the inner tube comprises a plurality of inner orifices, and the outer tube comprises a plurality of outer orifices.

8. The apparatus as claimed in claim 7, wherein each of the plurality of inner and outer orifices comprises at least 10 orifices.

9. The apparatus as claimed in claim 7, wherein the inner and outer orifices have inside diameter of from about 0.3 mm to about 2 mm.

10. The apparatus as claimed in claim 7, wherein the outer orifices are formed to face different directions as compared to the inner orifices.

11. The apparatus as claimed in claim 1, wherein the drying tank is dome-shaped.

12. The apparatus as claimed in claim 10, wherein the transfer unit is a vertical transfer unit formed between the cleaning bath and the drying tank.

13. A method of drying a substrate, comprising:
placing a substrate into a cleaning bath;
supplying liquid to the cleaning bath to clean the substrate;
transferring the clean substrate into a drying tank;
supplying a dry gas mixture for a predetermined amount of time into the drying tank;
supplying an inert gas for a predetermined amount of time into the drying tank; and
repeating the supplying of the dry gas mixture and the supplying of the inert gas to dry the substrate.

14. The method as claimed in claim 13, wherein supplying the dry gas mixture comprises supplying a mixture of an inert gas with any one of IPA, acetone, acetone nitrile, methanol, ethanol, and mixtures thereof.

15. The method as claimed in claim 13, wherein supplying the dry gas mixture for a predetermined amount of time and supplying the inert gas for a predetermined amount of time comprise spraying the gas mixture and the inert gas into the drying tank for about 10 to about 120 seconds.

16. The method as claimed in claim 13, wherein supplying the dry gas mixture and supplying the inert gas comprise spraying the gas mixture and the inert gas into the drying tank at a flow rate of from about 20 L/min to about 200 L/min.

17. The method as claimed in claim 13, wherein supplying the dry gas mixture and supplying the inert gas comprise providing the gas mixture and the inert gas at a temperature of from about 20° C. to about 250° C.

18. The method as claimed in claim 13, wherein repeating the supplying of the dry gas mixture and the supplying of the inert gas is performed at least twice.

19. The method as claimed in claim 13, wherein supplying liquid to the cleaning bath comprises supplying water.
